(19) United States
(12) Patent Application Publication
(10) Pub. No.: US 2006/0227594 A1
(43) Pub. Date: Oct. 12, 2006

(54) Memory unit using dynamic threshold voltage wordline transistors

(75) Inventors: Chua-Chin Wang, Kaohsiung City (TW); Tien-Hao Chen, Tuku Town (TW)

Correspondence Address: LADAS & PARRY, 26 WEST 61ST STREET, NEW YORK, NY, 10023, US

(73) Assignee: NATIONAL SUN YAT-SEN UNIVERSITY

(21) Appl. No.: 11/093,766

(22) Filed: Mar. 30, 2005

(51) Int. Cl. G11C 11/00

(52) U.S. Cl. 365/154

(57) ABSTRACT

The invention relates to an integrated circuit memory unit comprising: a memory cell, a switched bulk DC voltage source and a plurality of wordline-controlled transistors. Each of wordline-controlled transistors has a bulk connected to the switched bulk DC voltage source. When the data bit is read from the memory cell or the data bit is written into the memory cell, the bulks of the wordline-controlled transistors are switched to a first voltage level from the switched bulk DC voltage source so as to increase the drain current and obtain faster operation speed. When in an idle mode, the bulks of the wordline-controlled transistors are switched to a second voltage level from the switched bulk DC voltage source so as to obtain higher threshold voltage and decrease the leakage current.

### BACKGROUND OF THE INVENTION

1. Field of the Invention

The present invention relates to a memory unit, more particularly, a memory unit using dynamic threshold voltage wordline transistors

2. Description of the Related Art

Referring to FIG. 1, taking a static RAM for example, a conventional 6-T SRAM memory unit 10 comprises a total of 6 transistors. More specifically, the conventional 6-T SRAM memory unit 10 comprises a memory cell 13 and two wordline-controlled transistors 11 and 12 (N1, N2). The memory cell 13 is composed of two cross coupling inverters having four transistors. The WL signal is a wordline control line. When the WL is logical high (1), the wordline-controlled transistors 11 and 12 are opened, and the stored data bit is read from the memory cell 13 through complementary bit lines (BL, BLB); by contrast, external data can be written into the memory cell 13 through complementary bit lines (BL, BLB). On the contrary, when WL is logical low (0), the wordline-controlled transistors 11 and 12 are closed such that the written data bit is kept in the memory cell 13. Since the memory cell 13 drives complementary bit lines through the wordline-controlled transistors 11 and 12 until the voltage difference of the bitlines is differentiated by a sense amplifier, reading and writing speed of the memory cell 13 is determined by the currents of the wordline-controlled transistors 11 and 12.

Therefore, if the currents of the wordline transistors 11 and 12 are increased, the reading speed of the memory will be faster. Similarly, when data bit is written into the memory cell 13, the writing speed of the memory will be also faster if the currents of the wordline transistors 11 and 12 is large. However, the greater the current is, the more power dissipates. However, if low threshold voltage is adopted by the wordline-controlled transistors 11 and 12 to generate great currents, unnecessary power consumption will be introduced due to increased leakage current caused by the low threshed voltage of the transistors in the idle state.

Currently, there are several ways to increase operation speed of the memory. For example, a current-mode sense amplifier is used to accelerate reading speed by taking advantage of detecting current as compared with that of the voltage-mode sense amplifier. Another approach is to increase the current of wordline transistor in the memory cell by using low threshold voltage transistors as the wordline transistors. However, low threshold voltage will increase leakage current, which in turn results in large power consumption.

Therefore, it is necessary to provide a memory unit to resolve the above problems.

### SUMMARY OF THE INVENTION

One objective of the present invention is to provide an integrated circuit memory unit comprising: a memory cell, a switched bulk DC voltage source and a plurality of wordline-controlled transistors. Each wordline-controlled transistors has a bulk connected to the switched bulk DC voltage source. Thus, the threshold voltage of each wordline-controlled transistor is controlled by the switched bulk DC voltage source. When a data bit is read from the memory cell or the data bit is written into the memory cell, the bulks of the wordline-controlled transistors are switched to a first voltage level from the switched bulk DC voltage source. When the memory unit is in an idle mode, the bulks of the wordline-controlled transistors are switched to a second voltage level from the switched bulk DC voltage source. The first voltage level is higher than the second voltage level.

According to the invention, the memory unit can realize high speed operation in the memory cell using dynamic threshold voltage wordline transistors by changing the bulk voltage of the wordline-controlled transistor while data are read from the memory cell or data are written into the memory cell (i.e. in the access mode).

Besides, the memory unit of the invention can decrease leakage current when the memory cell is in the idle state by changing the bulk voltage of the wordline-controlled transistors, therefore saving idle state power consumption.

### BRIEF DESCRIPTION OF THE DRAWINGS

FIG. 1 shows a conventional memory unit.

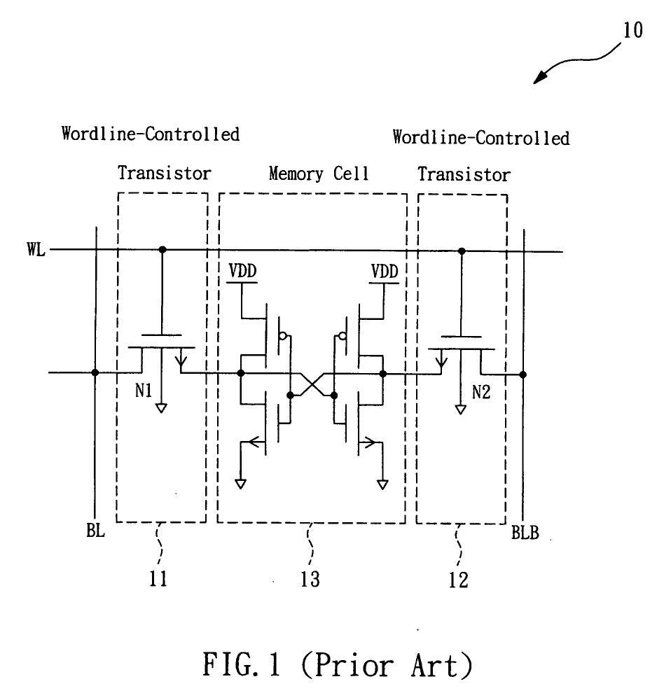

FIG. 2 shows a memory unit according to a first embodiment the invention.

FIG. 3 shows a simulated circuits with a changing bulk voltage, according to the invention.

FIG. 4 shows a simulated response of drain current when bulk voltage changes, according to the invention.

FIG. 5 shows a compared figure concerning the reading speed of the memory unit of the invention and the conventional memory unit.

FIG. 6 shows a compared figure concerning the writing speed of the memory unit of the invention and the conventional memory unit.

FIG. 7 shows a memory unit according to a second embodiment the invention.

FIG. 8 shows a memory unit according to a third embodiment the invention.

FIG. 9 shows a memory unit according to a fourth embodiment the invention.

FIG. 10 shows a memory unit according to a fifth embodiment the invention.

### DETAILED DESCRIPTION OF THE INVENTION

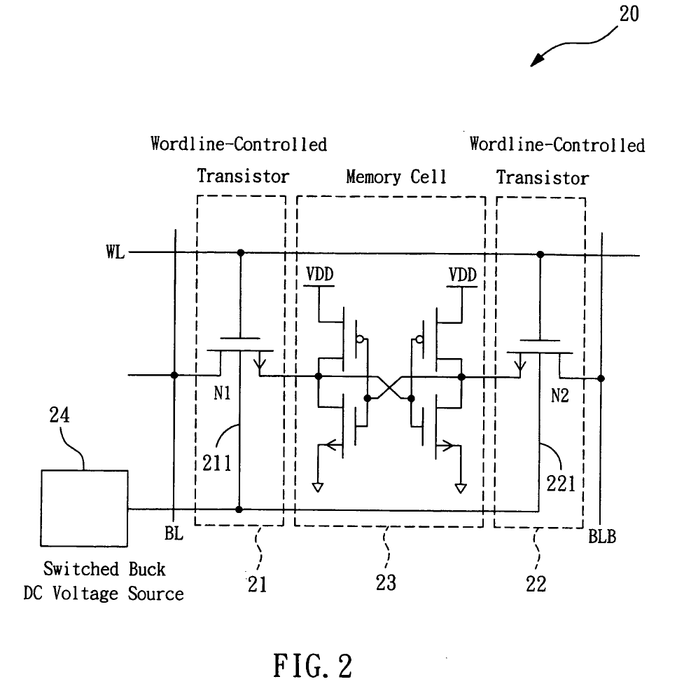

Referring to FIG. 2, according to a first embodiment of the invention, an integrated circuit memory unit 20 of the invention comprises two wordline-controlled transistors 21, 22, a memory cell 23 and a switched bulk DC voltage source 24. The memory cell 23 comprises two cross coupling inverters having four transistors. Each of the wordline-controlled transistors has a bulk connected to the switched bulk DC voltage source 24. For example, the wordline-controlled transistor 21 has a bulk 211 connected to the switched bulk DC voltage source 24, and the wordline-controlled transistor 22 has a bulk 221 connected to the switched bulk DC voltage source 24. The memory unit 20 is a 6T (six transistors) type memory unit.

Therefore, a threshold voltage of each wordline-controlled transistors is controlled by the switched bulk DC voltage source 24. When the data bit is read from the memory cell or the data bit is written into the memory cell, that is, in the access state, the bulk of the wordline-controlled transistors is switched to a first voltage level from the switched bulk DC voltage source 24. When in the idle mode, the bulks of the wordline-controlled transistors are switched to a second voltage level from the switched bulk DC voltage source 24. The first voltage level is higher than the second voltage level.

$$\begin{matrix}{I}_{D} = {V}_{sat} {WC}_{ox} ( {V}_{GS} - {V}_{th} ) & ( 1 ) \\ {V}_{th} = {V}_{th 0} + γ ( \sqrt{\vert 2 {φ}_{F} + {V}_{SB} \vert} - \sqrt{\vert 2 {φ}_{F} \vert} ) & ( 2 ) \\ {V}_{th 0} = {φ}_{MS} + 2 {φ}_{F} + \frac{{Q}_{dep}}{{C}_{ox}} & ( 3 )\end{matrix}$$

Deep submicron drain saturation current formula is shown in Equation (1), wherein Vsat is the saturation velocity of carriers when the transistors are conducted. Obviously, if Vth is decreased, the drain saturation current will be increased such that the accessing speed of the memory will be increased. In the formulas about Vth, as shown in Equations (2) and (3), φ_{MS} is the distance between polysilicon gate and bulk. φ_{F}=(kT/q)ln(N_{sub}/nᵢ), wherein N_{sub} is the doping concentration of bulk. Q_{dep} is the charge of the depletion region. Generally, φ_{F}=0.25˜0.35V, Q_{dep}=\sqrt{4q∈ₛᵢ|φ_{F}|N_{sub}}, ∈ₛᵢ is dielectric constant of silicon crystal. γ=\sqrt{2q∈ₛᵢN_{sub}}/Cₒₓ and generally, γ=0.3˜0.4V^{1/2}. Among the above parameters, except for V_{SB}, all the others including V_{TH0}, γ and φ_{F} are determined by semiconductor process. Therefore, V_{TH0}, γ and φ_{F} may be regarded as constant and γ>0. When \sqrt{|2φ_{F}+V_{SB}|}=0, there will be a minimum value of Vth. Thus, when 2φ_{F}=−V_{SB}, i.e., 2φ_{F}=V_{BS}=0.5˜0.7V, Vth is at its minimum value while drain current is at the maximum value.

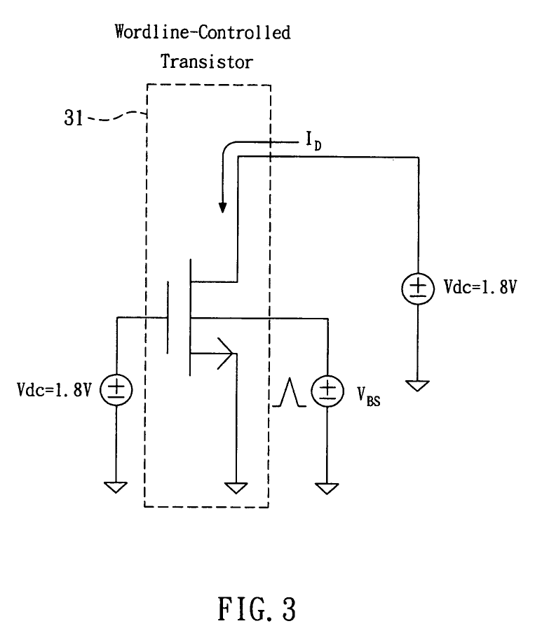

In FIG. 3, the circuit is used to prove the above deduction. A changing voltage V_{BS} is provided to the bulk of the wordline transistor 31 to observe influence on the drain current I_{D} by the changing bulk voltage VBS.

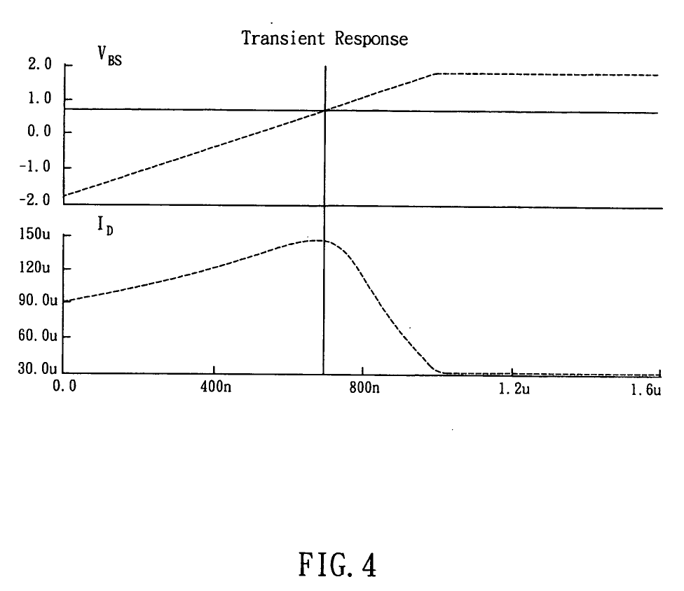

FIG. 4 is the simulated response of FIG. 3. When the bulk voltage V_{BS} is increased from −1.8V to +1.8V, the drain current I_{D} is at its maximum value when V_{BS}≈0.7V. Therefore, when the data bit is read from the memory cell or it is written into the memory cell, that is, in an access state, the bulk voltage V_{BS} can be switched to 0.7V to obtain the maximum drain current and realize a faster operation speed.

Leakage current is one of the sources for power consumption when the memory is in the idle state. The leakage current is analyzed in the following equations:

$$\begin{matrix}{I}_{leak} = \frac{{W}_{eff}}{{W}_{o}} {I}_{o} {10}^{- Vth / S} , & ( 5 ) \\ S \approx 2.3 {V}_{T} [ 1 + \frac{{C}_{d}}{{C}_{ox}} ] , & ( 6 )\end{matrix}$$

wherein Wo and Io are gate width and drain current, S is subthreshold swing parameter, V_{T} is thermal voltage, Cd is the junction capacitance of source and drain. As shown in Equation (5) and (6), if the threshold voltage is higher, the leakage current is lower; on the contrary, if the threshold voltage is lower, the leakage current is higher, resulting in the increased power consumption. Therefore, the bulk voltage V_{BS} is switched to 0V when the memory cell is in the idle state so as to obtain a higher threshold voltage and decrease the leakage current.

Given the above, referring to FIG. 2 again, when the data bit is read from the memory cell 23 or it is written into the memory cell 23, that is, in an access state, the switched bulk DC voltage source 24 provides the bulk 211, 221 of the wordline-controlled transistors 21, 22 with the first voltage level, for example, 0.7 V, so as to increase the drain current and obtain faster operation speed. When in an idle mode, the bulks 211, 221 of the wordline-controlled transistors 21, 22 are switched to the second voltage level, for example 0 V, from the switched bulk DC voltage source 24 so as to obtain higher threshold voltage and to decrease the leakage current. Generally, the first voltage level is higher than the second voltage level.

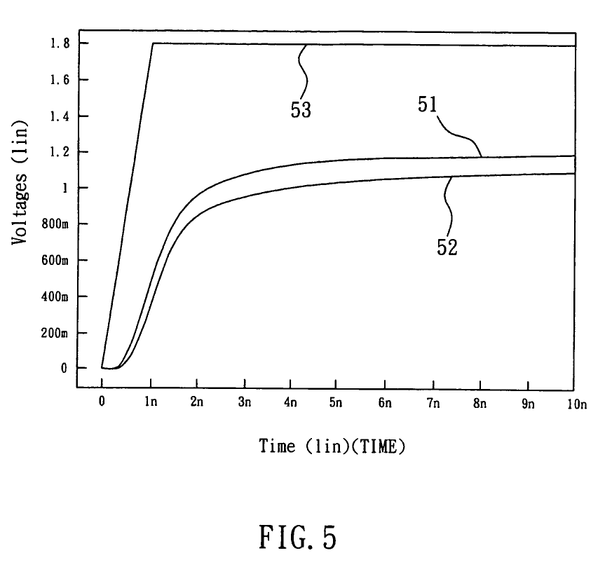

To demonstrate advantage of the memory unit of the invention, according to the first embodiment, the memory unit 20 is manufactured by the actual process of 0.18 μm 1P6M CMOS process technology provided by Taiwan Semiconductor Manufacturing Co., Ltd. Referring to FIG. 5, a first curve 51 is the simulated reading response of the memory unit of the invention, and a second curve 52 is the simulated reading response of the conventional memory unit when the data bit is read from the memory cell as indicated in a third curve 53 representing the WL signal. As shown in FIG. 5, the memory unit has a faster charging speed than that of the conventional memory unit.

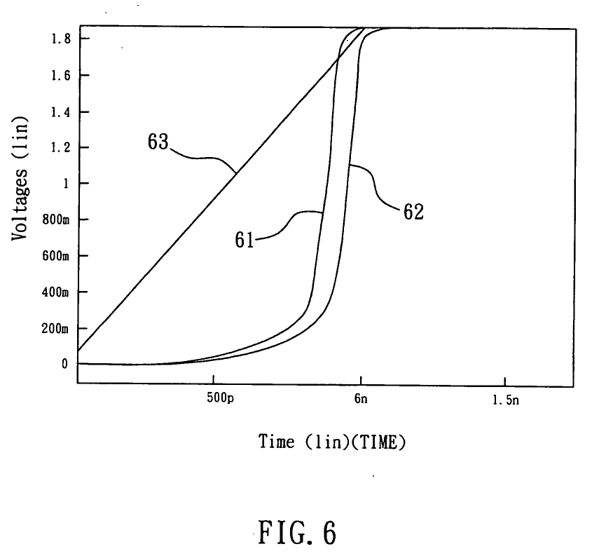

Referring to FIG. 6, a first curve 61 is the simulated writing response of the memory unit of the invention, and a second curve 62 is the simulated writing response of the conventional memory unit when the data bit is written into the memory cell as indicated in a third curve 63 representing the WL signal. As shown in FIG. 6, the memory unit has a faster writing speed than that of the conventional memory unit.

As for power dissipation, a 4 Kb memory is simulated and the power consumption of the memory cells is calculated when the wordline-controlled transistor is provided a dynamic threshold voltage by V_{BS}=0V or 0.7V. Power consumption is only 182 mW while the power of the same size memory using a fixed low threshold voltage wordline controlled transistors is 221 mW. Therefore, the memory unit of the invention has a power saving of 17.6% than the conventional memory unit using the low threshold voltage.

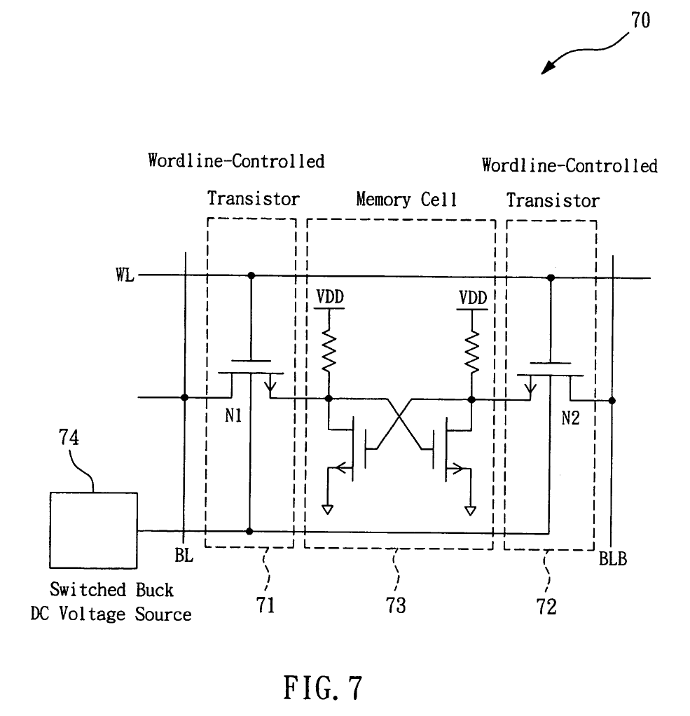

Referring to FIG. 7, according to a second embodiment of the invention, an integrated circuit memory unit 70 of the invention comprises two wordline-controlled transistors 71, 72, a memory cell 73 and a switched bulk DC voltage source 74. The memory cell 73 comprises two transistors. Each wordline-controlled transistors has a bulk connecting to the switched bulk DC voltage source 74. The memory unit 70 is a loaded resistance 4T (four transistors) SRAM type memory unit.

Similarly, when the data bit is read from the memory cell 73 or the data bit is written into the memory cell 73, that is, in an access state, the bulks of the wordline-controlled transistors are switched to a first voltage level from the switched bulk DC voltage source 74. When in an idle mode, the bulks of the wordline-controlled transistors are switched to a second voltage level from the switched bulk DC voltage source 74. The first voltage level is higher than the second voltage level.

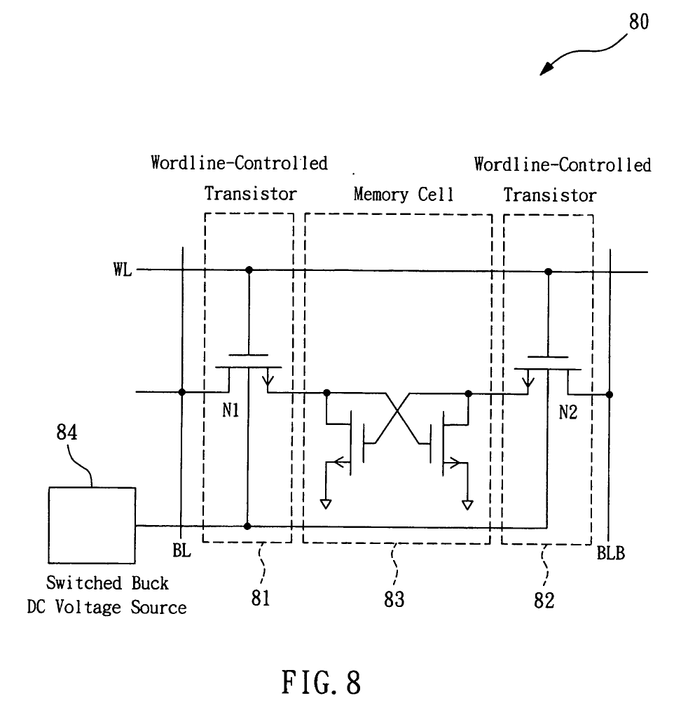

Referring to FIG. 8, according to a third embodiment of the invention, an integrated circuit memory unit 80 of the invention comprises two wordline-controlled transistors 81, 82, a memory cell 83 and a switched bulk DC voltage source 84. The memory cell 83 comprises two transistors. Each wordline-controlled transistors has a bulk connecting to the switched bulk DC voltage source 84. The memory unit 80 is a 4T (four transistors) SRAM type memory unit without load.

Similarly, when the data bit is read from the memory cell 83 or data is written into the memory cell 83, that is, in an access state, the bulks of the wordline-controlled transistors are switched to a first voltage level from the wordline-controlled transistors are switched to a second voltage level from the switched bulk DC voltage source 84. The first voltage level is higher than the second voltage level.

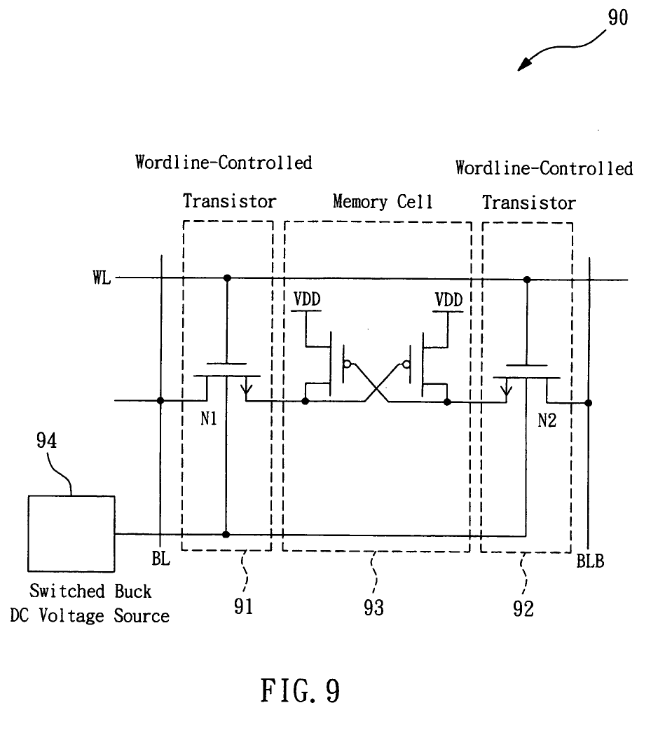

Referring to FIG. 9, according to a fourth embodiment of the invention, an integrated circuit memory unit 90 of the invention comprises two wordline-controlled transistors 91, 92, a memory cell 93 and a switched bulk DC voltage source 94. The memory cell 93 comprises two transistors. Each wordline-controlled transistors has a bulk connecting to the switched bulk DC voltage source 94. The memory unit 90 is a 4T (four transistors) SRAM type memory unit without load.

Similarly, when the data bit is read from the memory cell 93 or the data bit is written into the memory cell 93, that is, in an access state, the bulks of the wordline-controlled transistors are switched to a first voltage level from the switched bulk DC voltage source 94. When in an idle mode, the bulks of the wordline-controlled transistors are switched to a second voltage level from the switched bulk DC voltage source 94. The first voltage level is higher than the second voltage level.

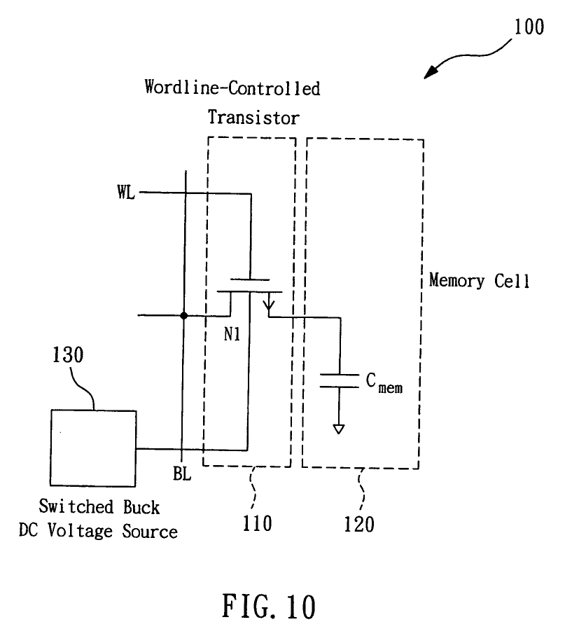

Referring to FIG. 10, according to a fifth embodiment of the invention, an integrated circuit memory unit 100 of the invention comprises a wordline-controlled transistors 110, a memory cell 120 and a switched bulk DC voltage source 130. The memory cell 120 represents a DRAM. The wordline-controlled transistor 110 has a bulk connecting to the switched bulk DC voltage source 130. The memory unit 100 is a DRAM type memory unit.

Similarly, when the data bit is read from the memory cell 120 or the data bit is written into the memory cell 120, that is, in an access state, the bulks of the wordline-controlled transistors are switched to a first voltage level from the switched bulk DC voltage source 130. When in an idle mode, the bulks of the wordline-controlled transistors are switched to a second voltage level from the switched bulk DC voltage source 130. The first voltage level is higher than the second voltage level.

Therefore, the memory unit of the invention is applicable for SRAM, DRAM, output buffer, etc. When the data bit is read from the memory cell or it is written into the memory cell, the switched bulk DC voltage source provides the bulk of the wordline-controlled transistors with the first voltage level so as to increase the drain current and obtain faster operation speed. When in an idle mode, the switched bulk DC voltage source provides the bulk of the wordline-controlled transistors with the second voltage level so as to obtain higher threshold voltage and decrease leakage current.

While an embodiment of the present invention has been illustrated and described, various modifications and improvements can be made by those skilled in the art. The embodiment of the present invention is therefore described in an illustrative, but not restrictive, sense. It is intended that the present invention may not be limited to the particular forms as illustrated, and that all modifications which maintain the spirit and scope of the present invention are within the scope as defined in the appended claims.

What is claimed is:

1. A public-access e-commerce service portal providing a user access to an internet, said portal comprising:
a computer including a display screen, a card reader adapted to read financial account information from a card, an input device adapted to provide alphanumeric and screen-coordinate information selected by the user, a drive unit adapted to read data from and write data to a removable data storage medium, and a printer unit, said computer being programmed to permit a user to selectively operate the units after said user enters a valid log-on ID, to establish a log-on ID for a new user after receiving answers manually input to the computer by the new user in response to predetermined demographic questions, and programmed to test the validity of financial account information, of PIN number and of log-on ID entries made by users;
a video camera, which inputs video images, connected to the computer, said computer being programmed to use said video camera to provide video-conference service to the user;
a telecommunications link adapted to connect the computer to an e-commerce intranet providing free services to the user, said free services including information resources and free access to selected e-commerce intranet sites and live contact with an intranet agent at an e-commerce service facility.

2. The portal of claim 1 further comprising a second telecommunications link, said second link being a switched link, said computer being further programmed to initiate a call back over the switched link when a service selected by the user requires a fee to be paid by the user.

3. The portal of claim 1 further comprising a paid-service indicator adjacent said card reader, said indicator connected to the computer to indicate when the computer is providing a paid service that has elapsed-time charges.

4. The portal of claim 1 wherein the computer is programmed to provide an idle-time display including full motion video entertainment clips, said computer re-initiating the idle-time display after a user enters a valid log-on ID after the user selects a free service and then does not make a further selection within a predetermined time period.

5. The portal of claim 1 further comprising an office service unit, said computer being programmed to provide word processing services.

6. The portal of claim 1 further comprising a laptop service unit including electric power and data connectors for use by a laptop computer.

7. The portal of claim 1 further comprising multiple carrels, said carrels being connected to a shared first link and adapted to respond to a respective separate second call-back telecommunications link to transfer user ID and PIN number information between the e-commerce service facility and the user.

8. The portal of claim 1, further comprising means for substituting a log-on display for an idle-time display for a limited period of time.

9. The portal of claim 1 further comprising means for limiting use of a free audio-visual service within a predetermined period of time.

10. The portal of claim 1 further comprising demo means for selectably implementing free demo displays including one of said full motion video entertainment clips, said demo displays being more extensive than said clip, and means for limiting the frequency of implementing said free demo.

11. The portal of claim 1 further comprising a private booth adapted to enclose a user and said computer.

12. A public-access e-commerce service network, said, network comprising:
a plurality of e-commerce portals, each portal having a video camera that inputs video images, a computer adapted to read financial account information from a card, respond to alphanumeric and screen-coordinate information selected by the user, read data from and write data to a removable data storage medium, selectively print information for the user, and provide video-conference service to a user, said computer being programmed to permit a user to selectively operate the units after said user enters a valid log-on ID, programmed to establish a log-on ID for a new user after receiving answers manually input to the computer by the new user in response to predetermined demographic questions, and programmed to test the validity of financial account information, of PIN number and of log-on ID entries made by users; and
a respective telecommunications link adapted to connect each of the computers to an e-commerce intranet, said intranet providing free services to the user, said free services including information resources sponsored by members of the intranet, and user access to selected e-commerce intranet sites, and to an e-commerce service facility.

13. The network of claim 12 wherein said intranet service facility provides pre-paid accounts enabling users to obtain paid intranet services.

14. The network of claim 13 wherein said intranet service facility provides pre-paid cards enabling users to obtain paid intranet services.

15. The network of claim 12 wherein said intranet service facility further comprises means for providing paid e-commerce support services.

16. A method of providing public access to e-commerce activities comprising the steps of:
providing a log-on ID to a user upon receiving answers from the user to predetermined questions;
providing selectable access to a plurality of paid and free services after validating a user ID entered by a user, said free services including access to selected e-commerce intranet sites, said paid services including video-conference service using a video camera that inputs video images;
providing access to each paid service selected by a user after validating a respective PIN number entered by the user.

17. The method of claim 16 wherein the portal provides a plurality of free services to the user using a first link, and provides the log-on ID to the user and receives the log on ID and PIN number from the user by using a separate, switched second communications link.
